(19) United States
(12) Patent Application Publication
(10) Pub. No.: US 2025/0199338 A1
(43) Pub. Date: Jun. 19, 2025

(54) AUGMENTED REALITY GLASSES LEG, PREPARATION METHOD THEREOF AND AUGMENTED REALITY DEVICE

(71) Applicant: GOERTEK TECHNOLOGY CO., LTD., Qingdao (CN)

(72) Inventors: Pengfei WANG, Qingdao (CN); Liang FAN, Qingdao (CN)

(21) Appl. No.: 19/064,259

(22) Filed: Feb. 26, 2025

Related U.S. Application Data
(63) Continuation of application No. PCT/CN2023/124778, filed on Oct. 16, 2023.

(30) Foreign Application Priority Data
Oct. 27, 2022 (CN) 202211328618.1

(51) Int. Cl. G02C 11/02; G02B 27/01

(52) U.S. Cl. CPC G02C 11/02; G02B 27/0176; G02B 2027/0178

(57) ABSTRACT

Disclosed are an AR glasses leg, a preparation method thereof and an AR device. The AR glasses leg includes a main body, a decorative layer and a skin-friendly layer; the main body includes an inner side portion and an outer side portion; the outer side portion and the inner side portion are butt-jointed in the radial direction of the main body and are enclosed to form a cavity with at least one end open; the inner side portion and the outer side portion are of an integrally-formed structure; the decorative layer is provided at the surface of the outer side portion, and the skin-friendly layer is provided at the surface of the inner side portion.

### CROSS-REFERENCE TO RELATED APPLICATIONS

The present application is a continuation application of International Application No. PCT/CN2023/124778, filed on Oct. 16, 2023, which claims priority to Chinese patent application No. 202211328618.1, entitled in “AUGMENTED REALITY GLASSES LEG, PREPARATION METHOD THEREOF AND AUGMENTED REALITY DEVICE” and filed on Oct. 27, 2022. The disclosures of the above-mentioned applications are incorporated herein by reference in their entireties.

### TECHNICAL FIELD

The present application relates to the technical field of augmented reality (AR) products, and in particular to an AR glasses leg and a preparation method thereof, and an AR device.

### BACKGROUND

Wearable AR products have attracted widespread attention due to their small size, powerful functions and good user experience. As wearable products, the touch of the legs close to the human body and their appearance are very important, which greatly affects the user's wearing experience of the product.

The existing AR glasses leg usually adopts a splicing design of two shells, which is assembled together using snaps and other methods. This design results in obvious splicing seams on the surface of the legs, which reduces the consistency of the product appearance; and the existence of the splicing seams greatly increases the difficulty of the product's waterproof design.

At the same time, due to the high thermal conductivity of conventional metal surface treatment, the user will feel cool when the legs touch the human body. As the contact area of the product increases, the phenomenon of low temperature touch becomes more serious, and it is particularly obvious in winter.

### SUMMARY

The main purpose of the present application is to provide an AR glasses leg, aiming to obtain an AR glasses leg with good waterproof effect, beautiful appearance and good touch.

To achieve the above-mentioned purpose, the AR glasses leg proposed by the present application includes:
a main body including an inner side portion and an outer side portion; the outer side portion and the inner side portion are butted against each other in a radial direction of the main body to enclose a cavity with at least one end open, and the inner side portion and the outer side portion are an integrally formed structure;
a decorative layer provided at a surface of the outer side portion; and
a skin-friendly layer provided at a surface of the inner side portion.

In an embodiment, the skin-friendly layer is an acrylic coating, a polyurethane coating, a rubber paint coating or an epoxy resin coating; and/or
the main body is made of magnesium-lithium alloy.

In an embodiment, the decorative layer is made of metal or ceramic, and a linear dividing line is formed between the decorative layer and the skin-friendly layer.

In an embodiment, the decorative layer is made of bright nickel, pearl nickel, black nickel, black chrome, gold, imitation gold, titanium nitride, titanium carbonitride, tungsten carbide, diamond-like carbon or boron nitride.

The present application also provides a preparation method of an AR glasses leg, including:
providing a metal pipe, and hydraulically expanding and forming the metal pipe to form a semi-finished product; the semi-finished product includes an inner side portion and an outer side portion divided in a radial direction;
performing a pre-treatment operation on the semi-finished product;
spraying a skin-friendly layer on a surface of the inner side portion; and
plating a decorative layer on a surface of the outer side portion to form the AR glasses leg.

In an embodiment, the pre-treatment operation includes mechanical treatment and/or chemical treatment; the mechanical treatment includes at least one of grinding and polishing, wiping and washing, and the chemical treatment includes at least one of chemical degreasing, chemical alkali washing, chemical pickling and activating.

In an embodiment, the decorative layer is plated by electroplating or magnetron sputtering.

In an embodiment, the skin-friendly layer is an acrylic coating, a polyurethane coating, a rubber paint coating or an epoxy resin coating; and/or
the metal pipe is made of magnesium-lithium alloy; and/or
the decorative layer is made of bright nickel, pearl nickel, black nickel, black chrome, gold, imitation gold, titanium nitride, titanium carbonitride, tungsten carbide, diamond-like carbon or boron nitride.

In an embodiment, the spraying the skin-friendly layer on the surface of the inner side portion includes:
spraying the skin-friendly layer on the semi-finished product entirely; and
performing laser engraving on the outer side portion to remove the skin-friendly layer of the outer side portion.

In an embodiment, after the performing the pre-treatment operation on the semi-finished product and before the spraying the skin-friendly layer on the semi-finished product entirely, the method further includes:
plating a protective layer on an entire surface of the semi-finished product.

In an embodiment, the protective layer is made of zinc, copper or semi-bright nickel; and/or
the protective layer is plated by electroplating.

In an embodiment, the performing laser engraving on the outer side portion to remove the skin-friendly layer of the outer side portion includes:
shielding the inner side portion, and performing laser engraving on the semi-finished product to remove the skin-friendly layer of the outer side portion.

The present application also provides an AR device, including:
a main body; and
two AR glasses legs connected to the main body;
the AR glasses leg is the above-mentioned AR glasses leg; or
the AR glasses leg is prepared using the preparation method of the AR glasses leg.

In the technical solution of the present application, the AR glasses leg includes a main body, a decorative layer and a skin-friendly layer. The main body includes an inner side portion close to the user's face and an outer side portion away from the user. The two are connected and enclosed in the radial direction of the main body to form a cavity with an opening, which can achieve a lightweight structure and facilitate the arrangement of circuits or components. The inner and outer side portions are an integrated structure, that is, they can be processed in one process. The processing efficiency is improved, the assembly process is omitted, and gaps on the main body are avoided, a seamless integrated structure is achieved, and the waterproof performance and appearance are effectively improved. At the same time, a skin-friendly layer is provided at the surface of the inner side portion, which can have a lower thermal conductivity than the metal material, thereby reducing the user's cold feeling and improving the touch experience of the AR glasses leg; and a decorative layer is provided at the surface of the outer side portion, so that two different textures are achieved and the appearance texture is improved.

### BRIEF DESCRIPTION OF THE DRAWINGS

In order to more clearly illustrate the embodiments of the present application or the technical solutions in the related art, the drawings required for use in the embodiments or the description of the related art will be briefly introduced below. Obviously, the drawings described below are only some embodiments of the present application. For those skilled in the art, other drawings can be obtained based on the structures shown in these drawings without paying creative work.

FIG. 1 is a schematic structural view of an AR glasses leg according to an embodiment of the present application.

FIG. 2 is a transverse cross-sectional view of the AR glasses leg shown in FIG. 1.

FIG. 3 is a flowchart of the steps of a preparation method of the AR glasses leg according to an embodiment of the present application.

FIG. 4 is a flowchart of the steps of the preparation method of the AR glasses leg according to another embodiment of the present application.

FIG. 5 is a flowchart of the steps of the preparation method of the AR glasses leg according to another embodiment of the present application.

The realization of the purpose, functional features and advantages of the present application will be further explained in conjunction with embodiments and with reference to the accompanying drawings.

### DETAILED DESCRIPTION OF THE EMBODIMENTS

The following will be combined with the drawings in the embodiments of the present application to clearly and completely describe the technical solutions in the embodiments of the present application. Obviously, the described embodiments are only part of the embodiments of the present application, not all of the embodiments. Based on the embodiments of the present application, all other embodiments obtained by those skilled in the art without creative work are within the protection scope of the present application.

It should be noted that all directional indications in the embodiments of the present application (such as up, down, left, right, front, back, etc.) are only used to explain the relative position relationship, movement status, etc. between the components under a certain specific posture (as shown in the accompanying drawings). If the specific posture changes, the directional indication will also change accordingly.

In addition, in the present application, descriptions such as “first”, “second”, etc. are only used for descriptive purposes and cannot be understood as indicating or implying their relative importance or implicitly indicating the number of the indicated technical features. Therefore, the features defined as “first”, “second” may explicitly or implicitly include at least one of the features. In the description of the present application, the meaning of “plurality” is at least two, such as two, three, etc., unless otherwise clearly and specifically defined.

In addition, the technical solutions between the various embodiments of the present application can be combined with each other, but it must be based on the fact that those skilled in the art can implement it. When the combination of technical solutions is contradictory or cannot be implemented, it should be deemed that such combination of technical solutions does not exist and is not within the protection scope required by the present application.

The present application proposes an AR glasses leg. The structure is applied to an AR device, so that an AR glasses leg with light weight, beautiful appearance, good waterproof effect and good touch can be obtained.

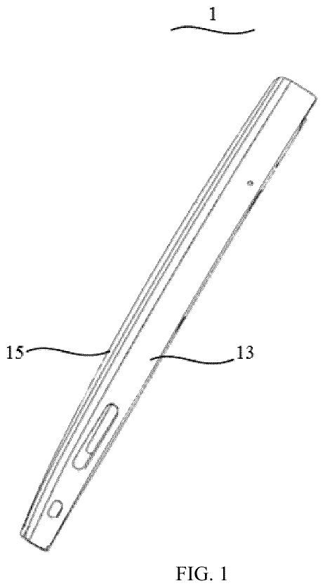

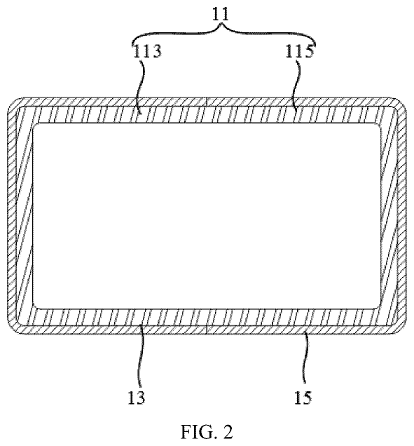

Referring to FIGS. 1 and 2, in an embodiment of the present application, an AR glasses leg 1 includes a main body 11 and a skin-friendly layer 13. The main body 11 includes an inner side portion 113 and an outer side portion 115. The outer side portion 115 and the inner side portion 113 are butted against each other in the radial direction of the main body 11, and enclose a cavity with at least one end open; the inner side portion 113 and the outer side portion 115 are an integrally formed structure; the decorative layer 15 is arranged on the surface of the outer side portion 115, and the skin-friendly layer 13 is arranged on the surface of the inner side portion 113.

It can be understood that the AR glasses leg 1 has an extended length, which can be suitable for wearing, and also has a certain cross-section in the horizontal direction. In this embodiment, the main body 11 is a hollow structure, which can achieve lightweight and facilitate the installation of components. The cross-sectional shape of the main body 11 can be circular, square or polygonal, etc., which is not limited here. The main body 11 includes an inner side portion 113 and an outer side portion 115, both of which can be regarded as two parts divided along the longitudinal direction of the main body 11. The inner side portion 113 is facing the user's face, and the outer side portion 115 is facing away from the user's face. The two are enclosed in the radial direction to form a cavity. At least one end of the cavity is open, so as to facilitate the installation of components or lines. The inner side portion 113 and the outer side portion 115 are an integrally formed structure. For example, when the materials of both are metal, they can be integrally formed by casting or forging, which is not limited here.

In order to further improve the lightweight of the AR glasses leg 1, the material of the main body 11 can be selected as magnesium-lithium alloy, which is the material with the lowest density among all metal structural materials, and can effectively reduce the weight of the AR glasses leg 1 and improve the wearing experience. The specific material ratio in the magnesium-lithium alloy will not be improved here, so it will not be elaborated on in detail, as long as it is an alloy composed of magnesium and lithium elements. In other examples, the material of the main body 11 can also be magnesium-aluminum alloy or magnesium rare earth alloy, etc., which has more application scenarios and higher structural strength. The material is also lightweight, which can reduce the weight of the head-mounted device and improve the experience. Alternatively, the material of the main body 11 can also be aluminum alloy, etc., which has a lower density, moderate strength, low price, and wider application.

The surface of the inner side portion 113 is provided with a skin-friendly layer 13. The material of the skin-friendly layer 13 is non-metallic, and the thermal conductivity is lower than that of metal, thereby improving its skin-friendly performance and avoiding the low temperature touch. Exemplarily, the material of the skin-friendly layer 13 is a polymer material, so it is light and has good structural stability. For example, the skin-friendly layer 13 is an acrylic coating, a polyurethane coating, a rubber paint coating or an epoxy resin coating, which has good wear resistance and waterproof performance, and is green and environmentally friendly and will not affect the human body. The thickness range of the skin-friendly layer 13 can be set according to the size of the specific main body 11. It should not be too thick, otherwise the material cost will increase; and it should not be too thin, otherwise it will affect its skin-friendly effect. Exemplarily, the thickness range of the skin-friendly layer 13 can be 3 μm to 6 μm, for example, 4 μm, 5 μm, etc.

In order to further enhance the appearance of the AR glasses leg 1, a decorative layer 15 is plated on the surface of the outer side portion 115. The material of the decorative layer 15 is metal or ceramic, so that two different texture effects can be formed on the surface of the AR glasses leg 1.

In the technical solution of the present application, the AR glasses leg 1 includes a main body 11 and a skin-friendly layer 13. The main body 11 includes an inner side portion 113 close to the user's face and an outer side portion 115 away from the user. The two are connected and enclosed in the radial direction of the main body 11 to form a cavity with an opening, which can achieve a lightweight structure and facilitate the setting of circuits or components. The inner side portion 113 and the outer side portion 115 are an integrally formed structure, that is, they can be processed in one process, which improves the processing efficiency and eliminates the assembly process. It can also avoid the appearance of gaps on the main body 11, realize a seamless integrated structure, and effectively improve the waterproof performance and appearance. At the same time, a skin-friendly layer 13 is provided at the surface of the inner side portion 113. The skin-friendly layer 13 may have a lower thermal conductivity than that of metal materials, thereby reducing the user's sense of coolness and improving the tactile experience of the AR glasses leg 1.

Please continue to refer to FIG. 1 and FIG. 2, in an embodiment, the material of the decoration layer 15 is metal or ceramic, and a linear dividing line is formed between the decoration layer 15 and the skin-friendly layer 13.

The decorative layer 15 made of metal or ceramic material can achieve better gloss texture and enhance aesthetics. Exemplarily, a linear dividing line is formed between the skin-friendly layer 13 and the decorative layer 15, and the straight line extends along the length extension direction of the main body 11, thereby achieving different appearances and touches on both sides of the AR glasses leg 1, further enhancing the aesthetics. In other examples, the dividing line can also be a curve or an irregular line. The thickness of the decorative layer 15 should not be too thick to save materials. Of course, its thickness should not be too thin, resulting in poor aesthetics, so 3 μm to 6 μm can be selected, for example, 4 μm, 5 μm, etc.

In an embodiment, the material of the decorative layer 15 is bright nickel, pearl nickel, black nickel, black chrome, gold, imitation gold, titanium nitride, titanium carbonitride, tungsten carbide, diamond-like carbon or boron nitride.

In this embodiment, in order to enhance the metal texture, the material of the decorative layer 15 is selected to be one of bright nickel, pearl nickel, black nickel, black chrome, gold, imitation gold, titanium nitride, titanium carbonitride, tungsten carbide, diamond-like carbon or boron nitride, which has good gloss and is more eye-catching.

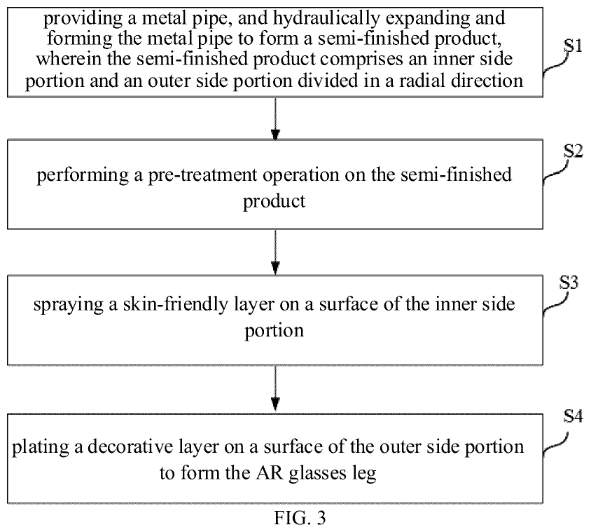

Referring to FIG. 3, the present application further proposes a preparation method of the AR glasses leg 1, and the method includes:
Step S1: providing a metal tube, and performing hydraulic expansion forming on the metal tube to form a semi-finished product; the semi-finished product includes an inner side portion 113 and an outer side portion 115 divided in a radial direction;
Step S2: performing pre-treatment operations on the semi-finished product;
Step S3: spraying the skin-friendly layer 13 on the surface of the inner side portion 113;
Step S4: plating a decorative layer 15 on the surface of the outer side portion 115 to form the AR glasses leg 1.

It is understandable that the AR glasses leg 1 is applied to a head-mounted device. In order to improve comfort, the head-mounted device needs to be lighter. Therefore, in order to reduce weight, the thickness of the metal tube selected in step S1 should not be too large, and a thin tube should be selected. The specific size can be selected according to actual conditions. The material of the metal tube is magnesium-lithium alloy, because it is the material with the lowest density among all metal structural materials, and it effectively reduces the weight of the AR glasses leg 1 and improves the wearing experience. In other embodiments, magnesium-aluminum alloy or other magnesium alloys may also be selected. The hydraulic bulging process is that when the liquid is pressurized, the volume remains unchanged and the pressure is evenly transmitted in all directions, so that the material is deformed along the mold under the most favorable conditions. The shape of the metal pipe is controlled by the outer bulging mold so that it is completely attached to the inside of the mold to obtain the semi-finished product of the AR glasses leg 1, that is, the outer contour structure of the main body 11 in the above-mentioned AR glasses leg 1, thereby forming an integrated seamless structure. The semi-finished product includes an inner side portion 113 and an outer side portion 115. Here, the structures of the two refer to the inner side portion 113 and the outer side portion 115 of the main body 11 in the above-mentioned embodiment, and will not be repeated here.

The semi-finished product formed by the hydraulic bulging process has the characteristics of light weight, high rigidity and strength, material saving, compact structure, and fewer processing steps, and can well meet the special requirements of lightweight AR glasses legs 1. Of course, in other embodiments, casting or forging processes can also be selected.

In step 2, in order to facilitate preparation, the surface of the semi-finished product is pre-treated so that its surface meets the conditions and state for plating. Specifically, the pre-treatment can be cleaning or re-setting the surface structure to improve the bonding force with the skin-friendly layer 13, which is not limited here. Of course, the size of the semi-finished product can also be processed before the surface treatment, for example, cutting or punching, to achieve the size and structure required for the AR glasses leg 1.

In step S3, the skin-friendly layer 13 is sprayed on the surface of the inner side portion 113. The spraying method is simple and easy to operate, low in cost, and suitable for mass production. Here, the skin-friendly layer 13 is made of a polymer material, and its thermal conductivity is lower than that of metal, thereby reducing the thermal conductivity of the inner side portion 113. When the AR glasses leg 1 is close to the user's face, the cold feeling can be reduced and the user's touch feeling can be improved. Exemplarily, the skin-friendly layer 13 is an acrylic coating, a polyurethane coating, a rubber paint coating or an epoxy resin coating, which has good wear resistance and waterproof performance, and is green and environmentally friendly and will not affect the human body. The spraying thickness of the skin-friendly layer 13 can be set according to actual conditions to ensure that the surface of the inner side portion 113 is covered with the skin-friendly layer 13.

After the inner side 113 is sprayed with the skin-friendly layer 13, in step S4, the decorative layer 15 is plated. Here, the plating process can also be electroplating or magnetron sputtering, or other conventional plating processes, with low processing costs. And the above-mentioned plating processes are all commonly used plating processes, and the specific plating process will not be described in detail here. Exemplarily, the material of the decorative layer 15 is metal, so as to achieve a better metallic gloss texture. For example, the material of the decorative layer 15 is bright nickel, pearl nickel, black nickel, black chrome, gold, imitation gold, titanium nitride, titanium carbonitride, tungsten carbide, diamond-like carbon or boron nitride. The thickness of the plated decorative layer 15 can be set as needed, for example, 3 μm to 6 μm, which saves materials and has a better texture. In this way, the preparation of the AR glasses leg 1 can be completed.

The preparation method of the present application has simple process, efficient process flow, low cost and is suitable for industrial mass production. At the same time, the prepared AR glasses leg 1 is a seamless integrated structure, and has a double texture design on the inner and outer sides, which improves its appearance and enables the user to have a good touch.

In an embodiment, the pre-treatment operation includes mechanical treatment and/or chemical treatment; the mechanical treatment includes at least one of grinding and polishing, wiping and water washing, and the chemical treatment includes at least one of chemical degreasing, chemical alkaline washing, chemical pickling and activation.

It is understandable that when the semi-finished product is made by hydraulic bulging/die casting or other processes, some oil stains or greasy dirt will usually remain on the surface. Therefore, in this embodiment, the pre-treatment operation may include mechanical treatment and/or chemical treatment to remove oil from the machine. For example, mechanical treatment includes at least one of grinding and polishing, wiping, and washing with clean water to remove oil and impurities on the surface; chemical treatment may also be used, such as chemical degreasing, or alkaline washing with alkaline substances. Alternatively, mechanical treatment and chemical treatment may be used simultaneously. In order to further improve the surface activity of the semi-finished product, the activation treatment can be used. The activation treatment can be chemically pickled with dilute sulfuric acid or acetic acid, or activated and cleaned with active substances. The concentration range of dilute sulfuric acid is 1-3 mol/L, and the activation time is about 30 seconds. A fresh semi-finished product surface can be obtained and the structural impact on the pipe base can be prevented. Of course, the activation treatment can also be carried out by electrolytic activation, which is not limited here. For example, after the above chemical treatment, you can choose to use clean water or deionized water for thorough cleaning to remove the residual reagents for activation and improve its surface binding ability.

Of course, in other embodiments, only one of the degreasing treatment, the activation treatment, and the re-cleaning may be selected.

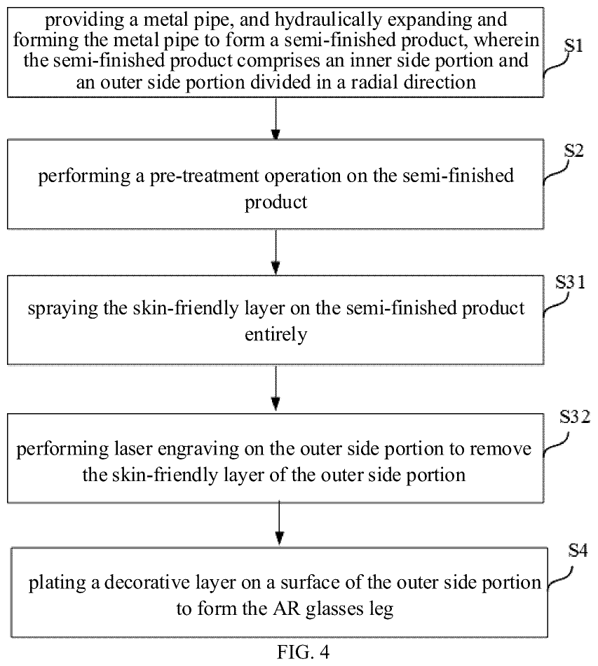

Referring to FIG. 4, in an embodiment, the specific steps of spraying the skin-friendly layer 13 on the surface of the inner side portion 113 include:
Step S31: spraying the skin-friendly layer 13 on the semi-finished product as a whole;
Step S32: performing laser engraving on the outer side portion 115 to remove the skin-friendly layer 13 of the outer side portion 115.

In this embodiment, in order to form the skin-friendly layer 13 of the inner side portion 113, the skin-friendly layer 13 is first sprayed on the entire semi-finished product through step S31, thereby simplifying the operation process and improving the spraying efficiency. Then, the skin-friendly layer 13 of the outer side portion 115 is removed by laser engraving, so that only the skin-friendly layer 13 of the inner side portion 113 is retained. This process can achieve a clear dividing line between the skin-friendly layer 13 and the decorative layer 15 through the precision of laser engraving, thereby achieving a distinction in texture between the two and further ensuring aesthetics.

In other examples, the skin-friendly layer 13 may be sprayed only on the inner side portion 113 by shielding the outer side portion 115.

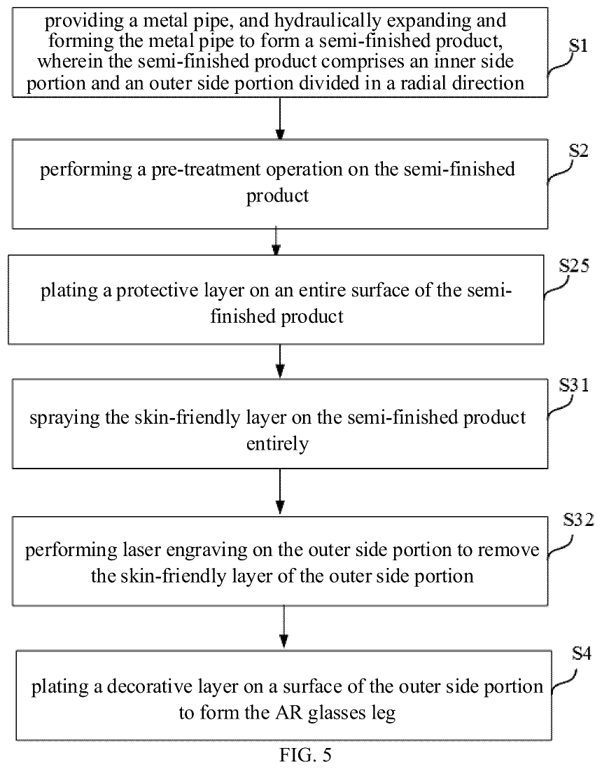

In conjunction with FIG. 5, in an embodiment, after the step of pre-treating the semi-finished product and before the step of spraying the skin-friendly layer 13 on the semi-finished product as a whole, the following step is further included:
Step S25: coating the entire surface of the semi-finished product with a protective layer.

In this embodiment, due to the need for laser engraving, in order to prevent the internal structure of the semi-finished product from being affected, a protective layer is plated on the surface of the semi-finished product as a whole before the pre-treatment operation is completed and the skin-friendly layer 13 is sprayed as a whole. The protective layer is used to protect the surface of the semi-finished product. When the skin-friendly layer 13 is removed by laser, it can withstand laser irradiation without significant changes in mechanical properties and chemical properties, thereby improving the internal structural strength of the AR glasses leg 1. Here, the protective layer can be plated by electroplating, so as to achieve good bonding strength with the skin-friendly layer and the decorative layer at the same time, and have corrosion resistance. In other examples, it can also be other coating processes, which are not limited here.

in an embodiment, the material of the protective layer is zinc, copper or semi-bright nickel.

In this embodiment, the material strength of the protective layer should be relatively high, for example, zinc, copper or semi-bright nickel, so that it has good anti-corrosion performance on the basis of a certain strength, thereby improving the performance protection of the semi-finished product.

in an embodiment, the step of laser engraving the outer side portion 115 to remove the skin-friendly layer 13 of the outer side portion 115 is specifically as follows:
Step S321: shielding the inner side portion 113, and performing laser engraving on the semi-finished product to remove the skin-friendly layer 13 of the outer side portion 115.

In this embodiment, in order to protect the skin-friendly layer 13, a shielding structure can be set during laser engraving to shield the position of the inner side portion 113, thereby improving the efficiency of laser engraving, ensuring the yield rate of the preparation method of the AR glasses leg 1, and effectively reducing the cost. The shielding structure is not limited, as long as it can block the laser penetration. And the shielding structure can be a plane, placed between the inner side portion 113 and the outer side portion 115, or it can match the shape of the inner side portion 113 to achieve complete coverage.

The present application further proposes an AR device, and the AR device includes a main body 11 and two AR glasses legs 1 connected to the main body 11. The AR glasses legs 1 are any of the AR glasses legs 1 described above, or the AR glasses legs 1 are prepared by any of the preparation methods of the AR glasses legs 1 described above. Since the AR device shell adopts all the technical solutions of all the aforementioned embodiments, it has at least the beneficial effects brought by the technical solutions of the aforementioned embodiments, which will not be repeated here one by one.

Exemplarily, the AR device may be AR glasses or an AR helmet, etc.

The above description is only some embodiments of the present application, and does not limit the patent scope of the present application. All equivalent structural changes made by using the contents of the present application specification and drawings under the inventive concept of the present application, or directly/indirectly applied in other related technical fields, are included in the protection scope of the present application.

1. An augmented reality (AR) glasses leg, comprising:
a main body comprising an inner side portion and an outer side portion; wherein the outer side portion and the inner side portion are butted against each other in a radial direction of the main body to enclose a cavity with at least one end open, and the inner side portion and the outer side portion are an integrally formed structure;
a decorative layer provided at a surface of the outer side portion; and
a skin-friendly layer provided at a surface of the inner side portion.

2. The AR glasses leg according to claim 1, wherein the skin-friendly layer is an acrylic coating, a polyurethane coating, a rubber paint coating or an epoxy resin coating; and/or the main body is made of magnesium-lithium alloy.

3. The AR glasses leg according to claim 1, wherein the decorative layer is made of metal or ceramic, and a linear dividing line is formed between the decorative layer and the skin-friendly layer.

4. The AR glasses leg according to claim 3, wherein the decorative layer is made of bright nickel, pearl nickel, black nickel, black chrome, gold, imitation gold, titanium nitride, titanium carbonitride, tungsten carbide, diamond-like carbon or boron nitride.

5. A preparation method of an AR glasses leg, comprising:
providing a metal pipe, and hydraulically expanding and forming the metal pipe to form a semi-finished product, wherein the semi-finished product comprises an inner side portion and an outer side portion divided in a radial direction;
performing a pre-treatment operation on the semi-finished product;
spraying a skin-friendly layer on a surface of the inner side portion; and
plating a decorative layer on a surface of the outer side portion to form the AR glasses leg.

6. The preparation method of the AR glasses leg according to claim 5, wherein the pre-treatment operation comprises mechanical treatment and/or chemical treatment; the mechanical treatment comprises at least one of grinding and polishing, wiping and washing, and the chemical treatment comprises at least one of chemical degreasing, chemical alkali washing, chemical pickling and activating.

7. The preparation method of the AR glasses leg according to claim 5, wherein the decorative layer is plated by electroplating or magnetron sputtering.

8. The preparation method of the AR glasses leg according to claim 5, wherein the skin-friendly layer is an acrylic coating, a polyurethane coating, a rubber paint coating or an epoxy resin coating; and/or
the metal pipe is made of magnesium-lithium alloy; and/or
the decorative layer is made of bright nickel, pearl nickel, black nickel, black chrome, gold, imitation gold, titanium nitride, titanium carbonitride, tungsten carbide, diamond-like carbon or boron nitride.

9. The preparation method of the AR glasses leg according to claim 5, wherein the spraying the skin-friendly layer on the surface of the inner side portion comprises:
spraying the skin-friendly layer on the semi-finished product entirely; and
performing laser engraving on the outer side portion to remove the skin-friendly layer of the outer side portion.

10. The preparation method of the AR glasses leg according to claim 9, wherein after the performing the pre-treatment operation on the semi-finished product and before the spraying the skin-friendly layer on the semi-finished product entirely, the method further comprises:
plating a protective layer on an entire surface of the semi-finished product.

11. The preparation method of the AR glasses leg according to claim 10, wherein the protective layer is made of zinc, copper or semi-bright nickel; and/or
the protective layer is plated by electroplating.

12. The preparation method of the AR glasses leg according to claim 9, wherein the performing laser engraving on the outer side portion to remove the skin-friendly layer of the outer side portion comprises:
shielding the inner side portion, and performing laser engraving on the semi-finished product to remove the skin-friendly layer of the outer side portion.

13. An AR device, comprising:
a main body; and
two AR glasses legs connected to the main body;
wherein the AR glasses leg is the AR glasses leg according to claim 1.

14. An AR device, comprising:
a main body; and
two AR glasses legs connected to the main body;
wherein the AR glasses leg is prepared using the preparation method of the AR glasses leg according to claim 5.
